(19) United States
(12) Patent Application Publication
(10) Pub. No.: US 2023/0389208 A1
(43) Pub. Date: Nov. 30, 2023

(54) RISER CARD MODULE AND SERVER WITH THE SAME

(71) Applicant: Shenzhen Fulian Fugui Precision Industry Co., Ltd., Shenzhen (CN)

(72) Inventors: KE-FENG YOU, Shenzhen (CN); LIN ZHANG, Shenzhen (CN)

(21) Appl. No.: 18/115,653

(22) Filed: Feb. 28, 2023

(30) Foreign Application Priority Data
May 27, 2022 (CN) 202210592451.3

(51) Int. Cl. H05K 5/02

(52) U.S. Cl. CPC H05K 5/0286

(57) ABSTRACT

A riser card module is provided. The riser card module is configured to be coupled to a server. The riser card module includes a carrier and an adapter interface. The carrier is configured to be electrically coupled to the server. The adapter interface is arranged on the carrier, and is electrically coupled to the carrier. The adapter interface is configured to be coupled to different external devices to expand different functions for the server via the carrier. The adapter interface is a mezzanine interface. A related server is also provided.

### FIELD

The subject matter herein generally relates to computer board technology, and particularly to a riser card module and a server with the same.

### BACKGROUND

A server may need to support an open computer project (OCP) network card and a host bus adapter (HBA), for example sometimes the server needs to support the OCP network card and sometimes the server needs to support the HBA. However, a space of a mainboard of the server cannot simultaneously receive the OCP network card and the HBA. The space of the mainboard of the server may be enlarged via designing, to simultaneously receive the OCP network card and the HBA. However, a circuit complexity of the mainboard may be increased, and a dexterity of the mainboard may be lower.

### SUMMARY

An embodiment of the present application provides a riser card module and a server with the same which are capable of supporting a OCP network card and a HBA without lowering a dexterity of a mainboard of the server.

In a first aspect, an embodiment of the present application provides a riser card module. The riser card module is configured to be coupled to a server. The riser card module includes a carrier and an adapter interface. The carrier is configured to be electrically coupled to the server. The adapter interface is arranged on the carrier, and is electrically coupled to the carrier. The adapter interface is configured to be coupled to different external devices to expand different functions for the service via the carrier. The adapter interface is a mezzanine interface.

According to some embodiments of the present application, the adapter interface is configured to be coupled to one of a group consisting of an open computer project network card and a host bus adapter card.

According to some embodiments of the present application, the carrier is a printer circuit board.

According to some embodiments of the present application, the carrier is configured to be electrically coupled to the server via an inter-integrated circuit bus and a peripheral component interconnect express bus, the inter-integrated circuit bus is parallel to the peripheral component interconnect express bus, the adapter interface is configured to be coupled to the server via the carrier, the inter-integrated circuit bus, and the peripheral component interconnect express bus.

According to some embodiments of the present application, the riser card module further includes a temperature detection unit. The temperature detection unit is arranged on the carrier, and is electrically coupled to the carrier. The temperature detection unit is configured to be electrically coupled to the server via the carrier. The temperature detection unit is arranged adjacent the adapter interface. The temperature detection unit is configured to detect a temperature of the external device coupled to the adapter interface, and is configured to provide the temperature of the external device coupled to the adapter interface to the server via the carrier.

According to some embodiments of the present application, the riser card module further includes a storage unit. The storage unit is arranged on the carrier, and is electrically coupled to the carrier. The storage unit is electrically coupled to the adapter interface. The storage unit is configured to store data created according to use of the adapter interface, and store program instructions.

In a second aspect, an embodiment of the present application provides a server. The server includes a riser card module. The riser card module is installed on the server. The riser card module includes a carrier and an adapter interface. The carrier is electrically coupled to the server. The adapter interface is arranged on the carrier, and is electrically coupled to the carrier. The adapter interface is configured to be coupled to different external devices to expand different functions for the service via the carrier. The adapter interface is a mezzanine interface.

According to some embodiments of the present application, the server further includes a complex programmable logic device. The complex programmable logic device is electrically coupled to the adapter interface via the carrier. The adapter interface transmits a preset signal to the complex programmable logic device via the carrier when the adapter interface is coupled to the external device. The complex programmable logic device detects whether the adapter interface is coupled to the external device according to a signal received form the adapter interface. The complex programmable logic device further determines the type of the external device coupled to the adapter interface according to the signal received from the adapter interface.

According to some embodiments of the present application, the complex programmable logic device is electrically coupled to the carrier via an inter-integrated circuit bus, and the complex programmable logic device is electrically coupled to the adapter interface via the inter-integrated circuit bus and the carrier.

According to some embodiments of the present application, the complex programmable logic device detects that the adapter interface is coupled to the external device when the complex programmable logic device receives the first present signal or the second present signal from the adapter interface.

According to some embodiments of the present application, the complex programmable logic device determines that the type of the external device coupled to the adapter interface is the open compute project network card when the complex programmable logic device receives the first present signal from the adapter interface, and the complex programmable logic device determines that the type of the external device coupled to the adapter interface is the host bus adapter when the complex programmable logic device receives the second present signal from the adapter interface.

According to some embodiments of the present application, the server further includes a central processing unit and a power supply. The central processing unit is electrically coupled to the complex programmable logic device and the power supply. The complex programmable logic device transmits a first power signal to the central processing unit when the type of the external device coupled to the adapter interface is the open compute project network card. The central processing unit controls the power supply to provide a first power to the open compute project network card via the carrier and the adapter interface according to the first power signal. The complex programmable logic device transmits a second power signal to the central processing unit when the type of the type of the external device coupled to the adapter interface is the host bus adapter. The central processing unit controls the power supply to provide a second power to the host bus adapter via the carrier and the adapter interface according to the second power signal.

According to some embodiments of the present application, the server further includes a platform controller hub. The platform controller hub is electrically coupled to the adapter interface via the carrier. The platform controller hub turns on a clock signal of the riser card module when the platform controller hub receives the first present signal or the second present signal from the adapter interface via the carrier.

According to some embodiments of the present application, the platform controller hub is electrically coupled to the carrier via a peripheral component interconnect express bus, and the platform controller hub is electrically coupled to the adapter interface via the peripheral component interconnect express bus and the carrier.

According to some embodiments of the present application, the server further includes a baseboard management controller. The baseboard management controller is electrically coupled to the adapter interface via the carrier. The baseboard management controller turns on a network controller sideband interface signal function of the open computer project network card when the type of the external device coupled to the adapter interface is the open compute project network card.

According to some embodiments of the present application, the baseboard management controller is electrically coupled to the carrier via an inter-integrated circuit bus, and the baseboard management controller is electrically coupled to the adapter interface via the inter-integrated circuit bus and the carrier.

Comparing to a nowadays technology, the disclosure has the following beneficial effects:

In the disclosure, via the riser card module, different external devices can be inserted into the adapter interface, and different external devices can be electrically coupled to the mainboard. Thus, different functions can be expended for the server and different needs of the server can be meet without lowing the dexterity of the mainboard.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a schematic view of an embodiment of a server and a riser card module.

FIG. 2 is a schematic view of an embodiment showing that the server and the riser card module of the FIG. 1 coupling a first network card module.

FIG. 3 is a schematic view of an embodiment showing that the server and the riser card module of the FIG. 2 coupling a host bus adapter.

FIG. 4 is a schematic view of another embodiment of a server.

### DETAILED DESCRIPTION

Implementations of the disclosure will now be described, by way of embodiments only, with reference to the drawings. The disclosure is illustrative only, and changes may be made in the detail within the principles of the present disclosure. It will therefore be appreciated that the embodiments may be modified within the scope of the claims.

It should be noted that, when an element is referred to as being “electrically coupled to” another element, the element can be directly on the other element or intervening elements may also be present. When an element is described as “electrically coupled to” another element, the coupling can be a contact connection, for example, can be a wired connection manner, or can be a contactless connection, for example, can be a contactless coupling manner.

Unless otherwise defined, all technical and scientific terms used in this text have the same meaning as commonly understood by persons skilled in the art to which the present invention belongs. The terms used in the description of the present invention are for the purpose of describing the specific embodiments only, and are not intended to limit the present invention. The term “and/or” used in this text includes any and all combinations of one or more of the associated listed items.

In the present disclosure. unless specified or limited otherwise. it is to be understood that terms such as “above,” “under,” “upper end,” “lower end,” “upper surface,” “lower surface,” “clockwise,” “counterclockwise,” “left,” and “right,” should be construed to refer to the orientation as then described or as shown in the drawings under discussion. These relative terms are for convenience of description and do not require that the device or element be constructed or operated in a particular orientation, shall not be construed to limit the present disclosure.

In the present disclosure, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “below,” or “on top of” a second feature may include an embodiment in which the first feature is right or obliquely “on,” “below,” or “on top of” the second feature, or just means that the first feature is at a height higher than that of the second feature; while a first feature “above,” “under,” or “on bottom of a second feature may include an embodiment in which the first feature is right or obliquely” above,” “under,” or “on bottom of” the second feature, or just means that the first feature is at a height lower than that of the second feature.

In addition, terms such as “first” and “second” are used herein for purposes of description and are not intended to indicate or imply relative importance or significance or to imply the number of indicated technical features. Thus, the feature defined with “first” and “second” may comprise one or more of this feature.

The following descriptions explain example embodiments of the present disclosure, with reference to the accompanying drawings. Unless otherwise noted as having an obvious conflict, the embodiments or features included in various embodiments may be combined.

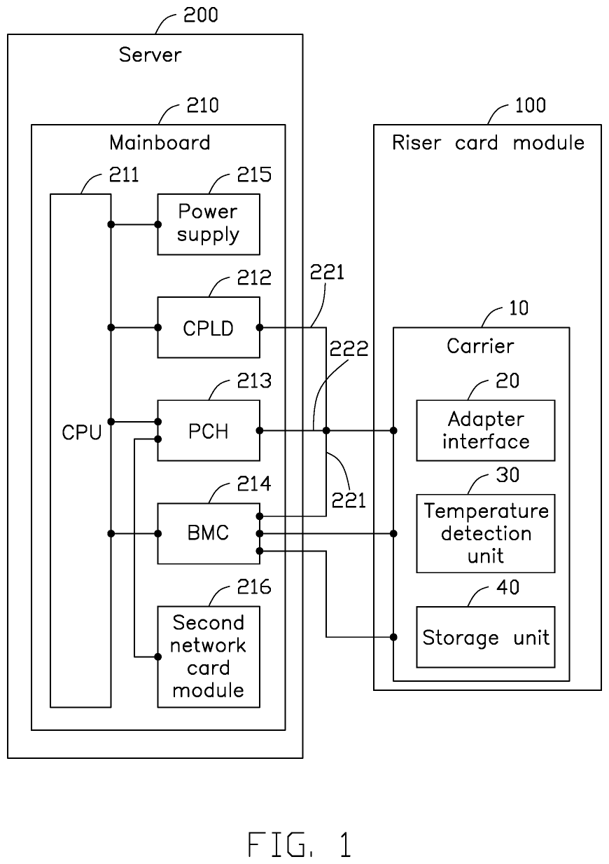

Referring to FIG. 1, a riser card module 100 is electrically coupled to a server 200 to be installed on the server 200. The riser card module 100 can provide a computer network service for the server 200 after the riser card module 100 is coupled to a wired network. Or, the riser card module 100 can provide a data storage service for the server 200 after the riser card module 100 is coupled to an external storage device.

It can be understood that, the server 200 can be applied in an electronic device. The electronic device includes, but is not limited to, a mobile terminal or an immobile terminal. The mobile terminal or the immobile terminal can be, for example, a ultra-mobile personal computer (UMPC), a handheld computer, a netbook, a personal digital assistant (PDA), a wearable device, a virtual reality device, a wireless USB flash drive, a Bluetooth speaker/headset, an on-vehicle device, an event data recorder, a security device, a medical device, or the like.

It can be understood that, the server 200 can be further electrically coupled to a display, a keyboard, a mouse, or other peripheral devices, to facilitate interaction with a user.

It can be understood that, the server 200 includes a mainboard 210. The riser card module 100 is electrically coupled to the mainboard 210 in the server 200. When the riser card module 100 is coupled to the wired network, the riser card module 100 can transmit a first information signal outputted from the mainboard 210 outward, and transmit a second information signal received from the external device to the mainboard 210 of the server 200. When the riser card module 100 is coupled to the external storage device, the riser card module 100 can store data outputted from the mainboard 210 to the external storage device, and can read data from the external storage device to the mainboard 210.

In the embodiment, the mainboard 210 includes a central processing unit (CPU) 211, a complex programmable logic device (CPLD) 212, a platform controller hub (PCH) 213, a baseboard management controller (BMC) 214, and a power supply 215.

It can be understood that, the CPU 211 is a control center of the server 200, and is configured to use various interfaces and lines to connect various parts of the server 200. For example, the CPU 211 is electrically coupled to the CPLD 212, the PCH 213, and the BMC 214, to control various parts of the server 200 via the CPLD 212, the PCH 213, and the BMC 214.

The CPLD 212, the PCH 213, and the BMC 214 each is electrically coupled to the riser card module 100. Thus, the CPU 211 can control the riser card module 100 to execute a corresponding instruction via the CPLD 212, the PCH 213, and the BMC 214, to achieve a network access for the server 200 or achieve a data storage for the server 200. In the embodiment, the riser card module 100 incudes a carrier 10, an adapter interface 20, a temperature detection unit 30, and a storage unit 40. The adapter interface 20, the temperature detection unit 30, and the storage unit 40 each is arranged on the carrier 10, and each is electrically coupled to the carrier 10. For example, in the embodiment, the adapter interface the temperature detection unit 30, and the storage unit 40 each is soldered on the carrier 10. Thus, the adapter interface 20, the temperature detection unit 30, and the storage unit 40 each is stably electrically coupled to the carrier 10.

In the embodiment, the carrier 10 can be a printed circuit board. It can be understood that, the disclosure is not limited to the material of the carrier 10. For example, in some embodiment, the carrier 10 can further be a ceramic circuit board, a flexible printed circuit, or other types of circuit boards.

In the embodiment, the adapter interface 20 can be, for example, a mezzanine interface. It can be understood that, the adapter interface 20 is configured to be coupled to one of a group consisting of a network card and an external storage device. For example, an open compute project (OCP) network card is inserted into the adapter interface 20 to couple to the adapter interface 20. Or, for example, a host bus adapter (HBA) which is configured to be coupled to an external storage device is inserted into the adapter interface 20 to couple to the adapter interface 20.

In the embodiment, the temperature detection unit 30 is arranged adjacent to the adapter interface 20. The temperature detection unit 30 is configured to detect a temperature value of the external device coupled to the adapter interface 20. The temperature value of the external device coupled to the adapter interface 20 can be used to monitor whether a potential failure of the external device coupled to the adapter interface 20 is existed. It can be understood that, if the temperature value of the external device coupled to the adapter interface 20 exceed a threshold value, the external device coupled to the adapter interface 20 can be determined to be at a potential failure state.

It can be understood that, the storage unit 40 is electrically coupled to the adapter interface 20 and the temperature detection unit 30. The storage unit 40 is configured to store data created according to use of each module, and/or store program instructions. It can be understood that, the disclosure is not limited to a type of the storage unit 40, the storage unit 40 can be a dynamic random access memory, a static random access memory, or other type storage unit. In the embodiment, the storage unit 40 is a field replacement unit (FRU) chip.

In the embodiment, the carrier 10 can be electrically coupled to the CPLD 212, the PCH 213, and the BMC 214. Thus, the adapter interface 20 is electrically coupled to the CPLD 212, the PCH 213, and the BMC 214 via the carrier 10. For example, the carrier 10 can be electrically coupled to the CPLD 121 and the BMC 214 via an inter-integrated circuit (I2C) bus 221. Thus, the adapter interface 20 can be electrically coupled to the CPLD 212 and the BMC 214 via the carrier 10 and the I2C bus 221. For example, the carrier 10 can be electrically coupled to the PCH 213 via a peripheral component interconnect express (PCIe) bus 222. Thus, the adapter interface 20 can be electrically coupled to the PCH 213 via the carrier 10 and the PCIe bus 222.

In the embodiment, the adapter interface 20 can transmit different signals to the CPLD 212, the PCH 213, and the BMC 214 according to different electronic devices coupled to the adapter interface 20, thus the mainboard 210 can distinguish a type of the external device coupled to the adapter interface 20 according to a signal received from the adapter interface 20.

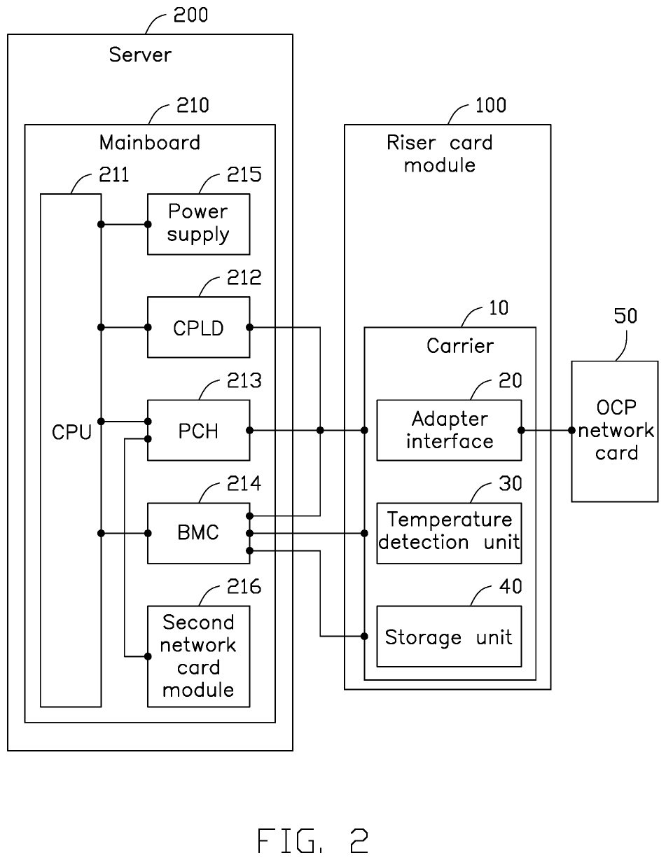

In detail, referring also to FIG. 2, a schematic view showing that the server 200 and the riser card module 100 being coupled to the OCP network card 50 is shown. The adapter interface 20 is coupled to the OCP network card 50. The OCP network card 50 is configured to be coupled to the wired network to provide the computer network service for the server 200 via the carrier 10 and the adapter interface 20.

In the embodiment, the OCP network card 50 can be, for example an OCP2.0 network card. It can be understood that, the OCP network card 50 can be other type of a first network card module, the disclosure is not limited herein.

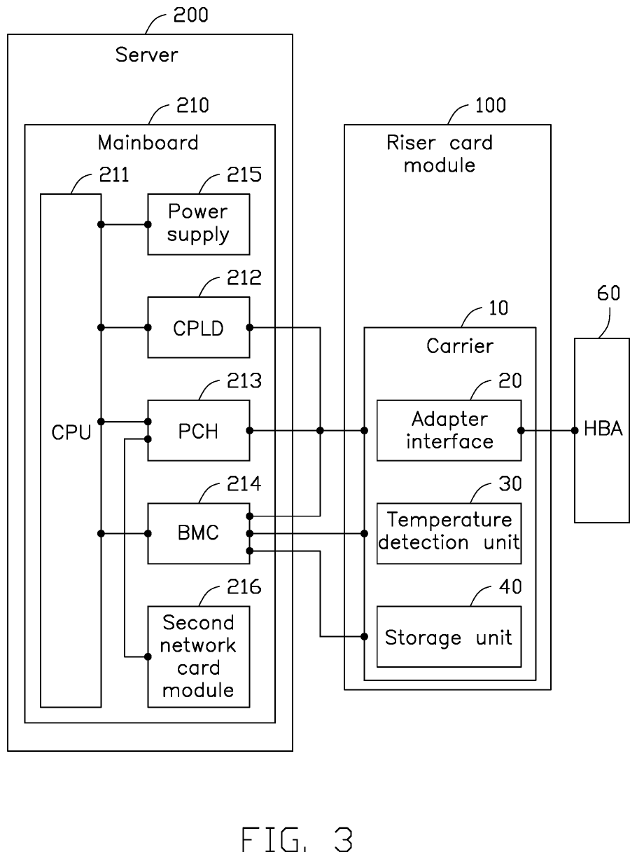

Referring also to FIG. 3, a schematic view showing that the server 200 and the riser card module 100 being coupled to the HBA 60 is shown. The adapter interface 20 is coupled to the HBA 60. The HBA 60 can be configured to be coupled to the external storage device to provide the data storage service for the server 200.

It can be understood that, via the riser card module 100, different external devices can be inserted into the adapter interface 20. Thus, different external devices each can be coupled to the server 200 via the same carrier 10 and the same adapter interface 20. Thereby, without increasing the circuit complexity of the mainboard 210, different functions can be expended for the server 200, and different requirements of the server 200 can be met.

In detail, when the first network card module 50 is inserted into the adapter interface the adapter interface 20 may transmit a first present signal (for example a present signal=0) to the CPLD 212, the PCH 213, and the BMC 214 via the carrier 10. When the HBA 60 is inserted into the adapter interface 20, the adapter interface 20 may transmit a second present signal (for example a present signal=1) to the CPLD 212, the PCH 213, and the BMC 214 via the carrier 10.

The CPLD 212 can detect whether the adapter interface 20 is coupled to an external device according to the signal received form the adapter interface 20 via the carrier 10. The CPLD 212 can further determine the type of the external device coupled to the adapter interface according to the signal received from the adapter interface 20 via the carrier 10.

In the embodiment, when the CPLD 212 receives the first present signal or the second present signal from the adapter interface 20 via the carrier 10, the CPLD 212 can detect that the adapter interface 20 is coupled to the external device.

In the embodiment, when the CPLD 212 receives the first present signal from the adapter interface 20 via the carrier 10, the CPLD 212 determines that the type of the external device coupled to the adapter interface 20 is the OCP network card 50. When the CPLD 212 receives the second present signal from the adapter interface 20 via the carrier 10, the CPLD 212 determines that the type of the external device coupled to the adapter interface 20 is the HBA 60.

In some embodiments, when the CPLD 212 has determined the type of the external device coupled to the adapter interface 20, the CPLD 212 transmits a corresponding power signal to the CPU 211 according to the type of the external device coupled to the adapter interface 20. The CPU 211 can control the power supply 215 to provide a corresponding power to the external device coupled to the adapter interface 20 via the carrier 10 and the adapter interface 20 according to the corresponding power signal. Thus, the external device coupled to the adapter interface 20 can work normal no matter which type of the external device is coupled to the adapter interface 20.

In some embodiments, when the CPLD 212 determines that the type of the external device coupled to the adapter interface 20 is the OCP network card 50, the CPLD 212 can transmit a first power signal to the CPU 211. The CPU 211 controls the power supply 215 to provide a first power to the OCP network card 50 via the carrier 10 and the adapter interface 20 according to the first power signal. When the CPLD 212 determines that the type of the external device coupled to the adapter interface 20 is the HBA 60, the CPLD 212 can transmit a second power signal to the CPU 211. The CPU 211 controls the power supply 215 to provide a second power to the HBA 60 via the carrier 10 and the adapter interface 20 according to the second power signal.

In some embodiments, when the PCH 213 receives the first present signal or the second present signal, the PCH 213 turns on a clock signal of the riser card module 100. For example, the PCH 213 con control a clock generator of the server 200 or a clock generator of the riser card module 100 to provide a clock signal with a frequency of 100M Hertz. Thus, the riser card module 100 can work at a normal mode, but not work at a low consumption mode.

In some embodiments, when the BMC 214 receives the first present signal, the BMC 214 turns on a network controller sideband interface signal function of the first network card module. Thus, other electronic device can implement an out-of-band management of the server 200 via the first network card module after other electronic device access the network. The other electronic device can be a smart phone, a computer, a netbook, a personal digital assistant (PDA), a wearable device, or the like.

In some embodiments, the temperature detection unit 30 is electrically coupled to the BMC 214 via the carrier 10. Thus, the BMC 214 can monitor whether the potential failure of the external device coupled to the adapter interface 20 of the riser card module 100 is existed via the temperature detection module 30. For example, when a temperature value of the first network card module 50 detected by the temperature detection unit 30 exceed a corresponding threshold value, the BMC 214 can determine that the potential failure of the first network card module 50 is existed. For example, when a temperature value of the HBA 60 detected by the temperature detection unit 30 exceed a corresponding threshold value, the BMC 214 can determine that the potential failure of the HBA 60 is existed.

In the embodiment, the storage unit 40 is electrically coupled to the BMC 214 via the carrier 10. Thus, the BMC 214 can obtain information of each module (for example each of the carrier 10, the adapter interface 20, and the temperature detection unit 30) of the riser card module 100 from the storage unit 40. Thus, the information of each module can be display for the user, and the user can know the operation state of each module.

It can be understood that, in some embodiments, the mainboard 210 further includes a second network card module 216. The second network card module 216 is electrically coupled to the PCH 213. Thus, if the adapter interface 20 is coupled to the HBA 60, the second network card module 216 can provide the computer network service for the server 200 via the wired network.

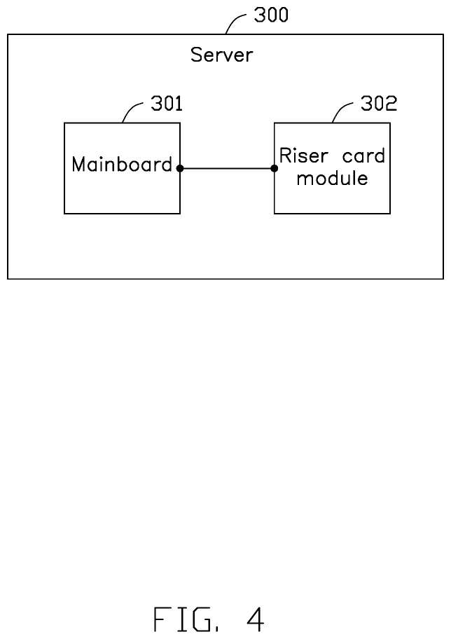

Referring to FIG. 4, a server of another embodiment is provided. The server 300 includes a mainboard 301 and a riser card module 302. The mainboard 301 can be a mainboard shown in the FIGS. 1-3. The riser card module 302 can be a riser card module shown in the FIGS. 1-3. The detail of the mainboard 301 and the riser card module 302 in the FIG. 4 can refer to the related description in the FIGS. 1-3, which will not be described herein. Namely, a distinction between the server 300 and the riser card module 302 in the FIG. 4 and the server and the riser card module in the FIGS. 1-3 is that: the riser card module 302 is arranged in the server 300 in the FIG. 4, and the riser card module is arranged external to the server in the FIGS. 1-3. Thus, in the disclosure, the riser card module can be a part of the server or can be independent from the server.

In the disclosure, via the riser card module, different external devices can be inserted into the adapter interface, and different external devices can be electrically coupled to the mainboard. Thus, different functions can be expended for the server and different needs of the server can be meet without lowing the dexterity of the mainboard. And, the carrier and the adapter interface do not need to be changed when a different external device is needed to be coupled to the mainboard of the server. Moreover, via the CPLD, the type of the external device coupled to the adapter interface can be automatically identified, for example a first network card module or the HBA coupled to the adapter interface can be automatically identified via the CPLD.

The embodiments described above are provided by way of example only, and various other modifications will be apparent to persons skilled in the field without departing from the scope of the invention as defined by the appended claims. It will be appreciated that, numerous variations and substitutions will occur to those skilled in the art without departing from the scope of the disclosure. Those variations and substitutions made in accordance with the spirit of the disclosure are within the scope of the present disclosure.

What is claimed is:

1. A riser card module configured to be coupled to a server, wherein:
the riser card module comprises a carrier and an adapter interface, the carrier is configured to be electrically coupled to the server;
the adapter interface is arranged on the carrier, and is electrically coupled to the carrier, the adapter interface is configured to be coupled to different external devices to expand different functions for the server via the carrier, the adapter interface is a mezzanine interface.

2. The riser card module according to claim 1, wherein:
the carrier is a printed circuit board.

3. The riser card module according to claim 2, wherein:
the adapter interface is configured to be coupled to one of a group consisting of an open computer project network card and a host bus adapter card.

4. The riser card module according to claim 2, wherein:
the carrier is configured to be electrically coupled to the server via an inter-integrated circuit bus and a peripheral component interconnect express bus, the inter-integrated circuit bus is parallel to the peripheral component interconnect express bus, the adapter interface is configured to be coupled to the server via the carrier, the inter-integrated circuit bus, and the peripheral component interconnect express bus.

5. The riser card module according to claim 2, wherein:
the riser card module further comprises a temperature detection unit, the temperature detection unit is arranged on the carrier, and is electrically coupled to the carrier, the temperature detection unit is configured to be electrically coupled to the server via the carrier, the temperature detection unit is arranged adjacent the adapter interface, the temperature detection unit is configured to detect a temperature of the external device coupled to the adapter interface, and is configured to provide the temperature of the external device coupled to the adapter interface to the server via the carrier.

6. The riser card module according to claim 2, wherein:
the riser card module further comprises a storage unit, the storage unit is arranged on the carrier, and is electrically coupled to the carrier, the storage unit is electrically coupled to the adapter interface, the storage unit is configured to store data created according to use of the adapter interface, and store program instructions.

7. A server comprising a riser card module, the riser card module being installed on the server, wherein:
the riser card module comprises a carrier and an adapter interface, the carrier is electrically coupled to the server;
the adapter interface is arranged on the carrier, and is electrically coupled to the carrier, the adapter interface is configured to be coupled to different external devices to expand different functions for the server via the carrier, the adapter interface is a mezzanine interface.

8. The server according to claim 7, wherein:
the carrier is a printed circuit board.

9. The server according to claim 8, wherein:
the adapter interface is configured to be coupled to one of a group consisting of an open computer project network card and a host bus adapter card.

10. The server according to claim 8, wherein:
the carrier is electrically coupled to the server via an inter-integrated circuit bus and a peripheral component interconnect express bus, the inter-integrated circuit bus is parallel to the peripheral component interconnect express bus, the adapter interface is electrically coupled to the server via the carrier, the inter-integrated circuit bus, and the peripheral component interconnect express bus.

11. The server according to claim 8, wherein:
the riser card module further comprises a temperature detection unit, the temperature detection unit is arranged on the carrier, and is electrically coupled to the carrier, the temperature detection unit is electrically coupled to the server via the carrier, the temperature detection unit is arranged adjacent the adapter interface, the temperature detection unit is configured to detect a temperature of the external device coupled to the adapter interface, and is configured to provide the temperature of the external device coupled to the adapter interface to the server via the carrier, the server is configured to determine whether a potential failure of the external device coupled to the adapter interface is existed according to the temperature of the external device.

12. The server according to claim 8, wherein:
the server further comprises a complex programmable logic device, the complex programmable logic device is electrically coupled to the adapter interface via the carrier, the adapter interface transmits a preset signal to the complex programmable logic device via the carrier when the adapter interface is coupled to the external device, the complex programmable logic device detects whether the adapter interface is coupled to the external device according to a signal received form the adapter interface, the complex programmable logic device further determines the type of the external device coupled to the adapter interface according to the signal received from the adapter interface.

13. The server according to claim 12, wherein:
the complex programmable logic device is electrically coupled to the carrier via an inter-integrated circuit bus, and the complex programmable logic device is electrically coupled to the adapter interface via the inter-integrated circuit bus and the carrier.

14. The server according to claim 12, wherein:
the complex programmable logic device detects that the adapter interface is coupled to the external device when the complex programmable logic device receives the first present signal or the second present signal from the adapter interface.

15. The server according to claim 12, wherein:
the complex programmable logic device determines that the type of the external device coupled to the adapter interface is the open compute project network card when the complex programmable logic device receives the first present signal from the adapter interface, and the complex programmable logic device determines that the type of the external device coupled to the adapter interface is the host bus adapter when the complex programmable logic device receives the second present signal from the adapter interface.

16. The server according to claim 12, wherein:
the server further comprises a central processing unit and a power supply, the central processing unit is electrically coupled to the complex programmable logic device and the power supply;
the complex programmable logic device transmits different power signals to the central processing unit according to different types of the external devices coupled to the adapter interface, the central processing unit controls the power supply to provide different powers to the adapter interface according to different power signals.

17. The server according to claim 8, wherein:
the server further comprises a platform controller hub, the platform controller hub is electrically coupled to the adapter interface via the carrier, the platform controller hub turns on a clock signal of the riser card module when the platform controller hub receives the first present signal or the second present signal from the adapter interface via the carrier.

18. The server according to claim 17, wherein:
the platform controller hub is electrically coupled to the carrier via a peripheral component interconnect express bus, and the platform controller hub is electrically coupled to the adapter interface via the peripheral component interconnect express bus and the carrier.

19. The server according to claim 8, wherein:
the server further comprises a baseboard management controller, the baseboard management controller is electrically coupled to the adapter interface via the carrier, the baseboard management controller turns on a network controller sideband interface signal function of the open computer project network card when the type of the external device coupled to the adapter interface is the open compute project network card.

20. The server according to claim 19, wherein:
the baseboard management controller is electrically coupled to the carrier via an inter-integrated circuit bus, and the baseboard management controller is electrically coupled to the adapter interface via the inter-integrated circuit bus and the carrier.
